(19) United States
(12) Patent Application Publication
(10) Pub. No.: US 2008/0014748 A1
(43) Pub. Date: Jan. 17, 2008

(54) Method and system for electronic spatial filtering of spectral reflectometer optical signals

(75) Inventor: Andrew Perry, Fremont, CA (US)

Correspondence Address: MARTINE PENILLA & GENCARELLA, LLP, 710 LAKEWAY DRIVE, SUITE 200, SUNNYVALE, CA, 94085, US

(73) Assignee: Lam Research Corporation.

(21) Appl. No.: 11/903,210

(22) Filed: Sep. 19, 2007

Related U.S. Application Data
(62) Division of application No. 10/625,243, filed on Jul. 22, 2003.

(51) Int. Cl. H01L 21/3065

(52) U.S. Cl. 438/689; 257/E21.218

(57) ABSTRACT

A method for determining endpoint of plasma processing of a semiconductor wafer includes providing a light source, and providing a lens system to collimate and align light from the light source to an active surface of the semiconductor wafer. A plurality of light detector fibers are interleaved among light source fibers which transmit light from the light source to the lens system. Reflected light from the active surface of the semiconductor wafer is received by a plurality of light detector fibers and provided to an imaging spectrometer. The received reflected light is analyzed by the imaging spectrometer, and matched to a model optical signal. The matched optical signal is selected to determine endpoint or other state of the plasma processing.

### CROSS REFERENCE TO RELATED APPLICATION

This application is a divisional of U.S. application Ser. No. 10/625,243, filed on Jul. 22, 2003. The disclosure of this prior application from which priority is claimed is incorporated herein by reference.

### BACKGROUND OF THE INVENTION

1. Field of the Invention

The present invention relates generally to spectral reflectometry, and more specifically to endpoint detection in semiconductor manufacturing using broad beam reflectometry, imaging spectrography, and two dimensional charge-coupled device (2-D CCD) array analysis.

2. Description of the Related Art

In the fabrication of semiconductor structures such as integrated circuits, memory cells, and the like, features, structures, and components are defined, patterned, and constructed in a series of manufacturing process steps on semiconductor wafers to create multi-layer integrated structures. Semiconductor wafers are processed through numerous operations during the semiconductor manufacturing process. Layers are added, and structures and features are defined, patterned, etched, removed, polished and many other processes in precisely controlled environments, during which the semiconductor wafers and the features defined and constructed thereon are closely monitored and analyzed to determine the endpoint of each process with exacting precision.

Typically, after each process, the wafer is examined to confirm the previous process was completed with an acceptable level of precision, and with a minimum of errors or nonuniformities. The various operating variables (e.g., event timing, gas pressure, concentrations, temperatures, etc.) of each process the wafer is processed through are recorded so that any changes in any variable may be quickly identified and potentially correlated to any errors or nonuniformities discovered when the wafer is examined. However, current structures and devices require in-situ monitoring and analysis to achieve the degree of precision required for fabrication with a level of economy and efficiency to enable manufacture on a scale commensurate with consumer and industry demand.

One common manufacturing process is plasma etch. In semiconductor fabrication, plasma etching is commonly used to etch conductive and dielectric materials to define features and structures therein. Plasma etch chambers are typically used which are capable of etching selected layers deposited over a substrate as defined by a photoresist mask. In general, the processing chambers are configured to receive processing gases, and radio frequency (RF) power is applied to one or more electrodes in the processing chamber. The pressure within the chamber is controlled in accordance with a particular desired process. Upon applying the desired RF power to the electrode(s), the process gases in the chamber are activated such that a plasma is created. The plasma is configured to perform the desired etching of the selected layers of a semiconductor wafer. In other implementations, plasma can be used for deposition processes as well.

In-situ monitoring and analysis in plasma etching operations typically involves spectral reflectometry or laser interferometry. By way of example, spectral reflectometers or laser interferometers are used to measure properties of thin films and thin film structures on semiconductor wafers to provide an endpoint call to a process so that an etching or deposition step can be stopped once a given amount of material has been removed or added to the wafer. Additionally, such processes are used to determine when etching has proceeded to within a specific preset distance from an underlying layer. One problem with current spectral reflectometry methods is that they generally interrogate the wafer using a beam of optical radiation (nominally 200-1000 nm in wavelength and hereinafter referred to as light) the diameter of which is of the order of the size of a die (the fundamental unit of the pattern repeated on the wafer).

If the feature of interest for the reflectometer measurement only occupies a very small fraction of the beam area as is the case in the manufacture of, by way of example, embedded dynamic random access memory (EDRAM), then the signal contrast will be very poor. One method to overcome the challenge is to use a very small beam, hereinafter also referred to as “spot,” and direct the spot around within the die until it falls on the region of interest. Such a method may be used in laser interferometry. In order to implement this method, however, an additional imaging camera, positioning hardware, and image recognition algorithms are required.

FIG. 1 shows a typical plasma etch system 100 illustrating in-situ monitoring hardware and processes. A plasma etch chamber 102 is shown having a wafer 106 disposed on a chuck 104. In order to accommodate in-situ process monitoring, the plasma etch system 100 can employ various additional features and structures. By way of example, the plasma etch system 100 illustrated in FIG. 1 includes a viewport 108 in the top of the etch chamber 100. An optics suite 112 is typically included which may include any of a plurality of light sources from broad beam to laser and detectors, depending on operator desires, process application, etc. In some applications, an x-y translational stage 110 is included for positioning of the optics suite 112 relative to the features or regions of interest, or for positioning of a separately mounted laser source 116.

A camera 114 is typically provided having a white light source for illumination, coupled with commercially available pattern recognition software. In a typical implementation, camera 114 looks at the entire wafer or some large subsection thereof. Once the camera 114 and pattern recognition software have identified a region of interest, x-y translational stage 110 drives the optics suite 112 to position the spot on the region of interest to make the endpoint call. In a typical spectral reflectometer configuration, a broad beam 120 is directed from over (above) wafer 106, and the reflected light returns essentially through the same broad beam 120 path.

In some applications, a laser source 116 is positioned on a side of plasma etch chamber 102 instead of in the top. The laser source 116, driven by an x-y translational stage similar to x-y translational stage 110, is precisely directed by the optics suite 112. A detector 118 then receives and analyzes a reflected optical pattern in the laser interferometer system.

In yet another system, the camera 114, having a light source for illumination and pattern recognition software, is implemented for a “whole-wafer” look to determine generalized whole wafer responses to plasma etch such as hot spots, whether the wafer edge is etching faster than the center, etc. Typically, this type of system uses a filter or combination of filters to look for a specific wavelength as an indicator of a particular state change in the wafer.

Each of the above described spectral reflectometer, laser interferometer, and filtering processes is well known in the art. One limitation illustrated in FIG. 1 is that as systems become more precise, and more complex, additional hardware is added. Additional hardware typically requires chamber design review and modification that can approach the point of being prohibitively expensive, and the increase in accuracy is often less than anticipated or desired.

In light of the foregoing, what is needed is a method and system that enable making an absolute etch-to-depth measurement, or even a relative depth change measurement, by automatic selection of a portion of the wafer die without the need for hardware positioning systems.

### SUMMARY OF THE INVENTION

Broadly speaking, the present invention fills these needs by providing methods and systems for endpoint and etch-to-depth determination that achieves the precision of narrow or small spot interferometry with broad beam simplicity. The present invention can be implemented in numerous ways, including as a process, an apparatus, a system, a device, a method, or a computer readable media. Several embodiments of the present invention are described below.

In one embodiment, a method for determining endpoint of a plasma etching operation of a surface on a wafer is provided. The surface of the wafer has features being etched, and the method includes applying collimated light onto the surface of the wafer, and detecting reflected light from the surface of the wafer. The reflected light is detected by discrete detection regions, and each detection region is configured to portray a unique signal across a frequency band. The method further includes identifying one of the detection regions to correlate with a model optical signal. Endpoint of the plasma etching operation is executed based on feedback from the identified one of the detected regions. The execution of endpoint is performed during the etching of the features on the surface.

In another embodiment, a system for etching a wafer is provided. The system is capable of determining endpoint of a plasma etching operation of a surface on a wafer, and the surface of the wafer has features being etched. The system includes a detector for detecting reflected light from the surface of the wafer. The reflected light is detected by discrete detection regions. Each detection region is configured to generate a specific optical signal across a frequency band. One of the detection regions is configured to correlate with a model optical signal, whereby endpoint of the plasma etching operation is based on feedback from an identified one of the detected regions.

In a further embodiment, a method for determining endpoint of plasma processing of a semiconductor wafer is provided. The method includes providing a light source, and providing a lens system to collimate and align light from the light source to an active surface of the semiconductor wafer. The method further provides for interleaving a plurality of light detector fibers among light source fibers. The light source fibers transmit light from the light source to the lens system, and terminate in a fiber optic aperture at the lens system. The light detector fibers are interleaved among the light source fibers at the fiber optic aperture. Light is transmitted through the lens system at the active surface of the semiconductor wafer, and reflected light is received from the active surface of the semiconductor wafer at the plurality of light detector fibers. The method additionally provides an imaging spectrometer, and for the transmitting of the received reflected light at the plurality of light detector fibers to the imaging spectrometer. The received reflected light is analyzed by the imaging spectrometer. The received optical signal is matched to a model optical signal. The matching optical signal is selected to determine endpoint of the plasma processing.

In still another embodiment, a plasma processing system for use in semiconductor manufacturing is provided. The plasma processing system includes a plasma processing chamber having an interior region, an exterior, and a viewport providing visual access to the interior region from the exterior. A light source is configured to provide a broad beam light for directing through the viewport onto an active surface of a semiconductor wafer positioned within the interior region of the plasma processing chamber. The plasma processing system further includes a plurality of detector optical fibers. Each of the plurality of detector optical fibers has a detection end and an analysis end, and each detection end is positioned in a fiber optic aperture of the lens system. The plasma processing system also includes an imaging spectrometer. The imaging spectrometer receives the analysis end of each of the plurality of detector optical fibers. A 2-D CCD detector array is included to analyze a received optical signal from each of the plurality of detector optical fibers. An endpoint of plasma processing is determined based on an analysis of the received optical signal from each of the plurality of detector optical fibers.

The advantages of the present invention over the prior art are numerous. One notable benefit and advantage of the invention is that some of the capability formerly achieved only with the precision and complexity of narrow spot interferometry is realized with the simplicity of broad beam reflectometry. Embodiments of the present invention do not require a separate camera and attendant separate illumination system(s), do not require pattern recognition software, or a motorized translational stage system. Embodiments return the precision of narrow spot interferometry with broad beam reflectometry that essentially create a series of parallel narrow beam reflectometers, but with a single broad beam.

Another benefit is the ability to incorporate embodiments of the present invention with plasma processing systems without significant chamber modification, without interfering with plasma formation and plasma flow in any manner, and without requiring extensive translational stages, optics suites, and the like requiring additional and continuing system modification.

Other advantages of the invention will become apparent from the following detailed description, taken in conjunction with the accompanying drawings, illustrating by way of example the principles of the invention.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIG. 1 shows a typical plasma etch system illustrating in-situ monitoring hardware and processes.

FIG. 2 is a spectrometer detection and analysis system in accordance with an embodiment of the present invention.

FIG. 3 illustrates an optical fiber aperture of the lens system as would be directed at the surface of a wafer in accordance with one embodiment of the invention.

FIG. 4 is a block diagram of spectrometry detection and analysis components in accordance with one embodiment of the present invention.

FIG. 5A illustrates the arrangement of detector fibers in the entrance slit of imaging spectrometer, in accordance with one embodiment of the invention.

FIG. 5B illustrates an exemplary plot of 2-D CCD array detection and analysis in accordance with one embodiment of the present invention.

FIG. 6A shows an exemplary beam spot as might be projected onto a semiconductor wafer, and representative locations of detector fibers in the optical fiber aperture, in accordance with one embodiment of the present invention.

FIG. 6B illustrates the projection of the beam spot of FIG. 6A onto an exemplary die, in accordance with an embodiment of the invention.

FIG. 7 is a flow chart diagram illustrating the method operations for making an endpoint call in plasma etch operations, in accordance with one embodiment of the present invention.

### DETAILED DESCRIPTION OF THE PREFERRED EMBODIMENTS

An invention for determining and selecting which region of a die to use to determine process end point in plasma etch operations is described. In preferred embodiments, methods and systems for the detection and analysis of optical signals using spectral reflectometry include implementing a 2-D CCD detector array to resolve outputs from a plurality of optical signals, and then matching the analyzed signals to model endpoint or exact depth signals to enable essentially absolute etch-to-depth and endpoint calls. In the following description, numerous specific details are set forth in order to provide a thorough understanding of the present invention. It will be understood, however, to one skilled in the art, that the present invention may be practiced without some or all of these specific details. In other instances, well known process operations have not been described in detail in order not to unnecessarily obscure the present invention.

As an overview, embodiments of the present invention provide either endpoint call or etch-to-depth functionality, and do so without design-intensive additional chamber hardware, voluminous pattern recognition software, and the like. As described above, the typical spectral reflectometer system uses a broad band light source, and has a large beam spot size, with an average spot size of approximately 12.5 mm in diameter. There is typically no attempt to resolve features within a die. White light is directed at the wafer surface from above, reflected light is returned upwards, and the reflectance from the wafer is analyzed as a function of wavelength. A weighted average is used to analyze an overall response across the die, with the weighted average accommodating such features and structures as hardmask, type of features being etched, area of open space, pattern density, etc. While the algorithm used to evaluate with a weighted average may be particularly useful for specific structures, e.g., patterns or dies with fairly constant and uniform feature layout, it is not without limitation. By way of example, if the feature of interest for the reflectometer measurement occupies only a very small fraction of the beam area (e.g., EDRAM patterns and features), then the signal contrast will be very poor.

One method to overcome this problem of analysis of regions in which the feature occupies only a very small fraction of the spot size of the broad band spectral reflectometer, is to move to a smaller beam size. By way of example, a simple laser such as that used in laser interferometer systems can have a spot size of approximately 50 micrometers (μm). In a large die of approximately 15 mm square, the small spot of the laser must be directed to cover a large area relative to spot size, but a much greater capability to identify and analyze specific features of interest is achieved. In order to move the spot around in the die, an additional imaging camera, sophisticated image recognition algorithms, additional optics suites, x-y translational stages, etc., are all required as described above.

Embodiments of the present invention seek to achieve some of the advantages of the small spot, but keep the simplicity and ease of implementation of the large spot spectrometry technology. Specifically, no additional cameras, stages, and so forth, are added that require chamber design modifications, or might possibly interfere with desired plasma properties. Embodiments of the present invention seek to analyze some of the regions in the footprint of the large spot while ignoring others as in the example of dies containing EDRAM or other embedded memory cells or other such features.

Embodiments of the present invention use essentially wholly electronic techniques to “steer” the beam on the die to identify and analyze regions of interest. A large diameter beam of approximately 12.5 mm in diameter is formed using a lens system that collimates light emitted from an optical fiber bundle. An exemplary 12.5 mm spot size is described as a typical wafer die size is approximately 12.5 mm. A larger or smaller spot can be implemented according to processing parameters and desires. Light reflected from the wafer passes back through the same lens system and is returned to the aperture of the fiber bundle. The fiber bundle also contains collection fibers, also referred to as detector fibers, that transmit this reflected light to a spectrometer.

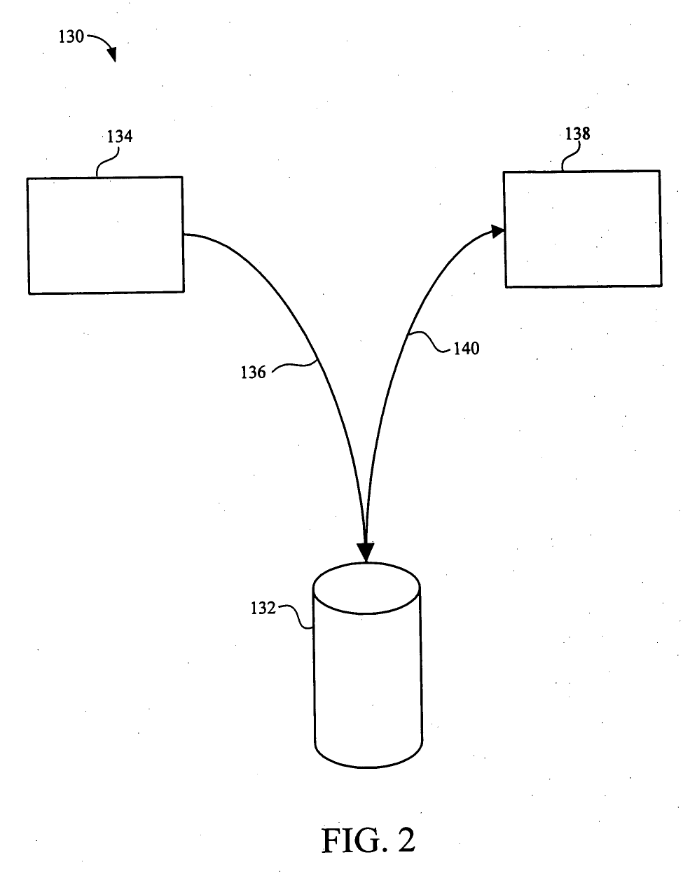

FIG. 2 is a spectrometer detection and analysis system 130 in accordance with an embodiment of the present invention. Components of the spectrometer detection and analysis system 130 include a light source 134, light source optical fiber bundle 136, lens system 132, detection fiber bundle 140, and imaging spectrometer 138.

Light source 134 includes, in one embodiment, a broad spectrum source, typically covering the wavelength range from 250 to 1000 nm, for providing the desired broad band light source that will be projected as a large spot on the wafer surface in a foot print of about the size of a die. In other embodiments, light source 134 can be a pulsed light source such as a xenon flashlamp, a dual light source such as deuterium/halogen, or a combination of a halogen light source and light emitting diodes.

Light source optical fiber bundle 136 transmits light from light source 134 to lens system 132. In one embodiment, light source optical fiber bundle includes a plurality of fibers for light transmission, with an exemplary bundle including 60-200 fibers, with embodiments ranging from as few as 20 fibers to approximately 200 fibers depending on such factors as fiber diameter, economy of fabrication, etc. In one embodiment of the invention, fibers selected in optical fiber bundle 136 are multi-mode optical fibers.

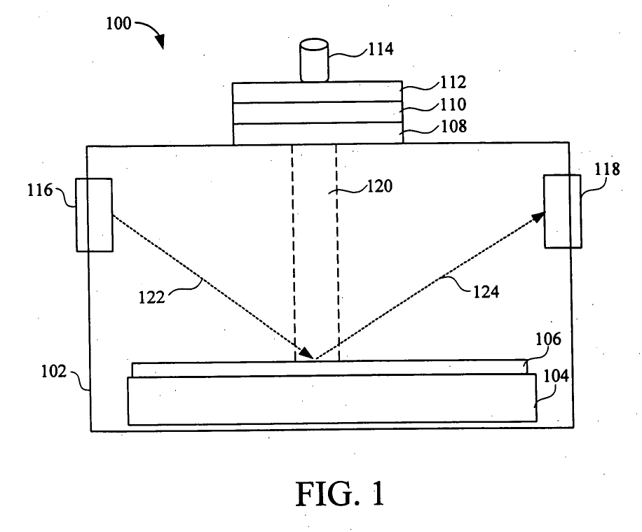

In one embodiment of the present invention, lens system 132 is provided to collimate light, and to spread the light received from the light source 134 by the light source optical fiber bundle 136. Lens system 132 collimates the light, spreads the light to a spot of approximately 12.5 mm in diameter, and aligns the light with the surface of the wafer 106 (see FIG. 1). In one embodiment, lens system 132 is positioned exterior to a plasma etch chamber, over a viewport located in a top region of the plasma etch chamber and providing visual access into the interior of the plasma etch chamber.

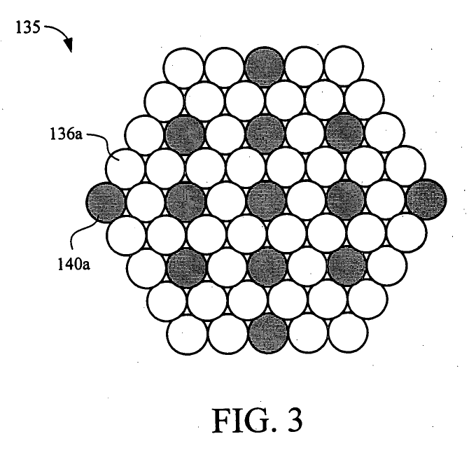

In one embodiment of the invention, lens system 132 not only collimates and directs light received from light source 134 through light source optical fiber bundle 136, but additionally lens system 132 interleaves detector fibers 140a (see FIG. 3 below) with light source fibers 136a (see FIG. 3 below). Lens system 132 thereby directs light received from light source 134 at the surface of the wafer 106 (see FIG. 1), and receives light reflected from the surface of the wafer 106. The received light is transmitted by detection fiber bundle 140 to imaging spectrometer 138.

FIG. 3 illustrates an optical fiber aperture 135 of lens system 134 (see FIG. 2) as would be directed at the surface of a wafer 106 (see FIG. 1) in accordance with one embodiment of the invention. FIG. 3 illustrates one embodiment of an arrangement of light source fibers 136a and detector fibers 140a within lens system 132 as seen from an optical fiber aperture 135 of lens system 132 as might be directed at the surface of wafer 106. Dark circles representing detector fibers 140a are interleaved with clear circles representing light source fibers 136a. In one embodiment, detector fibers 140a are dispersed throughout the optical fiber pattern presented at optical fiber aperture 135 of lens system 134. Such dispersal ensures detector fibers 140a receive reflection from essentially the entire footprint of the beam directed at the wafer surface 106.

Returning to FIG. 2, detection fiber bundle 140 transmits light received by detector fibers 140a (see FIG. 3) to imaging spectrometer 138. In one embodiment of the invention, detection fiber bundle 140 includes 13 detector fibers 140a, and in other embodiments the number of detector fibers 140a can range from about 5 to about 15 detector fibers 140a, depending on degree of resolution necessary and on imaging spectrometer 138 capability or capacity. In one embodiment, imaging spectrometer 138 includes a 2-D CCD detector array, described in greater detail below.

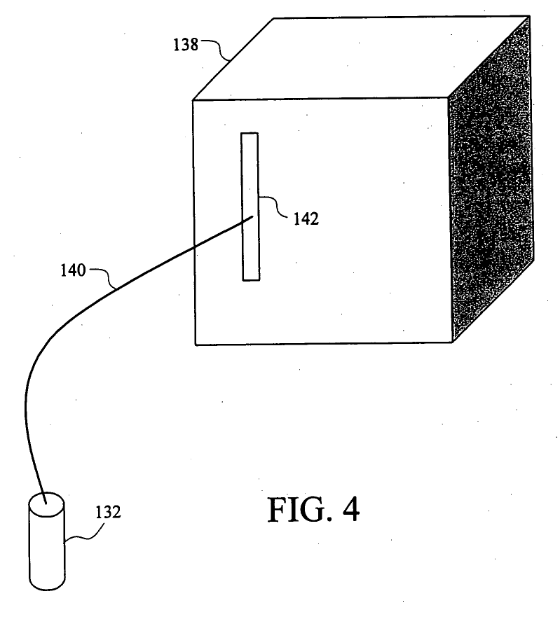

FIG. 4 is a block diagram of spectrometry detection and analysis components in accordance with one embodiment of the present invention. Lens system 132 includes detector fibers 140a (see FIG. 3) interleaved with light source fibers 136a (see FIG. 3). Detector fibers 140a are routed from lens system 132 to imaging spectrometer 138 through detection fiber bundle 140. At imaging spectrometer 138, detector fibers 140a are vertically aligned at imaging spectrometer entrance slit 142, as will be described in greater detail below.

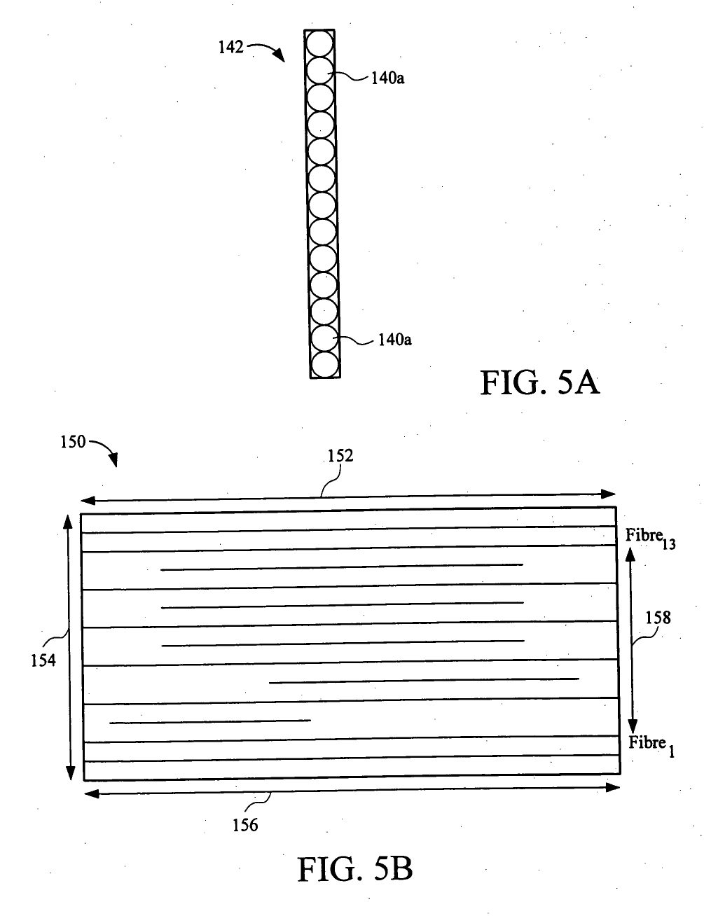

FIG. 5A illustrates the arrangement of detector fibers 140a in entrance slit 142 of imaging spectrometer 138 (see FIG. 4), in accordance with one embodiment of the invention. As described above, detector fibers 140a, interleaved with light source fibers 136a (see FIG. 3) in lens system 134 (see FIG. 4), are routed to imaging spectrometer 138 through detection fiber bundle 140 (see FIG. 4). In one embodiment of the invention, detector fibers 140a are aligned vertically to essentially exactly fill entrance slit 142. In one embodiment of the invention, at least five detector fibers 140a are arranged in entrance slit 142. In other embodiments, as many detector fibers 140a as are interleaved into optical fiber aperture 135 (see FIG. 3) of lens system 134 (see FIG. 2), are aligned in entrance slit 142, and in one embodiment 13 detector fibers 140a are routed to and aligned in entrance slit 142.

In one embodiment, the number of detector fibers 140a is limited by the capability of imaging spectrometer 138 to prevent overlap of the light from different fibers within, and in one embodiment of the invention, more than one imaging spectrometer 138 is configured to accommodate a sufficient number of detector fibers 140a for desired or necessary feature resolution.

In one embodiment, exact correlation between a specific location or position of a single detector fiber 140a within entrance slit 142 and a specific position in lens system 134 is not determined or maintained, and process analysis including end point call or etch-to-depth determination is based on analyzed wavelength irrespective of an exact detector fiber 140a location. As will be described in greater detail below, wavelength analysis is used to determine regions of interest on a wafer 106 (see FIG. 1), and once a region of interest has been identified, analysis of the reflectance from that feature proceeds regardless of the position of the detector fiber 140a in the lens system 134 or the entrance slit 142. In another embodiment, strict compliance is maintained to ensure essentially exact positional correspondence for each detector fiber 140a between a specific location in lens system 134 and position within the vertically oriented entrance slit 142.

FIG. 5B illustrates an exemplary plot 150 of 2-D CCD array detection and analysis in accordance with one embodiment of the present invention. 2-D CCD array analysis is known in the art, and FIG. 5B illustrates an implementation in accordance with an embodiment of the invention for end point detection and etch-to-depth measurement and monitoring. In FIG. 5B, upper x-axis 152 and left y-axis 154 represent a dimension of plot 150. A dimension of 2-D CCD array plot 150 is expressed in pixels in one embodiment of the invention. In one embodiment, upper x-axis length is 1024 pixels, and in one embodiment, upper x-axis length is 2048 pixels. In one embodiment, left y-axis height is 128 pixels, and in one embodiment, left y-axis height is 256 pixels. In one embodiment, the selected dimension of plot 150 establishes the scale in which the arrayed optical information is plotted.

In one embodiment of the invention, lower x-axis illustrates wavelength of the optical information. The 2-D CCD array plot 150 presents the measured information from a plurality of detector fibers, measured by an array of devices, and the information is plotted along a wavelength spectrum at a desired dimension or scale. In the vertical direction along right y-axis 158, each of the detector fibers 140a (see FIG. 5B) is plotted in an appropriate scale based on the amplitude of the signal with each of the detector fibers 140a illustrated in FIG. 5A having a corresponding position in the 2-D CCD plot 150. In the illustrated embodiment, Fibre₁ is plotted along a bottom region of 2-D CCD array plot 150, Fibre₁₃ is plotted along a top region of 2-D CCD array plot 150, and Fibres₂₋₁₂ (not shown) are plotted accordingly between the two extremes. In one embodiment, a desired number of pixels (not shown) is selected as empty or buffer bands between each of the vertically stacked plots of detector fiber 140a signals for clarity of plot and ease of perceiving the separate and distinct detector plots.

As shown in the embodiment illustrated in FIGS. 5A and 5B, each detector fiber 140a provides arrayed data across essentially entire wavelength spectra. In this manner, the signals from each of the detector fibers 140a, that collectively provide reflectance information across essentially an area corresponding to the size of a die on a semiconductor wafer, can be monitored and analyzed. In one embodiment, the monitoring and analysis enables mathematical selection of the detector fiber 140a or combination of detector fibers 140a providing the best signal contrast, or the best content of information in the reflectant signature for a given process in real time. This enables determination of which detector fiber 140a or combination of detector fibers 140a to examine, analyze, and monitor at run time. In one embodiment, each signal, each signal of interest, and/or each combination of signals can be compared to any of a plurality of models appropriate for the type of process, stage of fabrication, structure(s) being fabricated, pattern density, and so forth, to evaluate process progress (i.e., endpoint), film depth (i.e., etch-to-depth), and any of a plurality of desired process parameters. The detector fiber 140a selection is made in real time by a best match to an appropriate model, and then the detector fiber 140a, or combination of detector fibers 140a, is tracked through the fabrication process as appropriate or desired.

In one embodiment of the invention, the 2-D CCD detector array contained within imaging spectrometer 138 (see FIG. 4) resolves the signals from at least five detector fibers 140a, and up to a number of fibers that can be clearly resolved by imaging spectrometer 138, for display in 2-D CCD array plot 150. The signal from each of the detector fibers 140a is detected independently by the different regions of the 2-D CCD detector array within the imaging spectrometer 138, and the resulting data presented separately to an endpoint algorithm, and to the 2-D CCD array plot 150.

In one embodiment, the algorithm is a manual mode in which the endpoint recipe is programmed to use the output of a particular detector fiber 140a to determine the endpoint. The selected detector fiber 140a is dependent on wafer type, pattern on the die, and other parameters. In one embodiment, the detector fiber 140a selected is determined from the observed pattern presented on the 2-D CCD array plot 150. In such an embodiment, strict compliance is necessarily maintained between detector fiber 140a positions relative to the entrance slit 142 (see FIG. 5A) of imaging spectrometer 138 (see FIG. 4) and the optical fiber aperture 135 (see FIG. 3), and the orientation of a wafer 106 (see FIG. 1) in the plasma etch chamber would have to be known and maintained.

In another embodiment, the algorithm runs in parallel on the signals from all the detector fibers 140a, and the signal exhibiting the greatest signal contrast is selected for determination of endpoint.

In yet another embodiment, the algorithm runs in parallel on the signals from all the detector fibers 140a, and the signals are arbitrated using the error level from each signal to determine which endpoint to return to the tool. In this embodiment, the signal from each fiber is compared in real time with a model. For each of the detector fibers, the parameters in the model (e.g., the thickness of the layers on the wafer, open area, surface roughness, etc.) are adjusted to achieve a best “goodness of fit” between the model and the signal from the detector fiber. The goodness of fit can be viewed as an error signal that indicates how well the model is matching the real signal from the wafer returned by each detector fiber 140a. The endpoint returned to the tool is then calculated from the fiber signal having the lowest error signal. In one embodiment, if there is no error signal that is below a predetermined limit then the system would return an alarm to the tool.

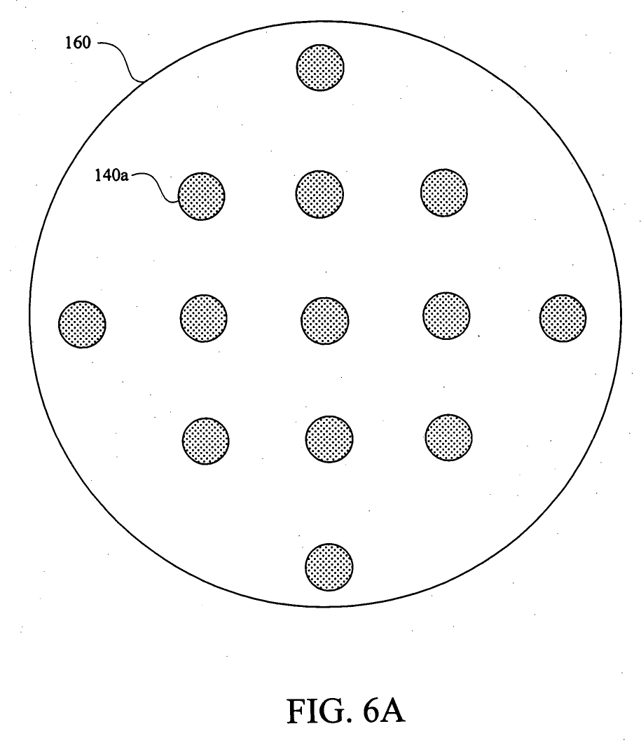

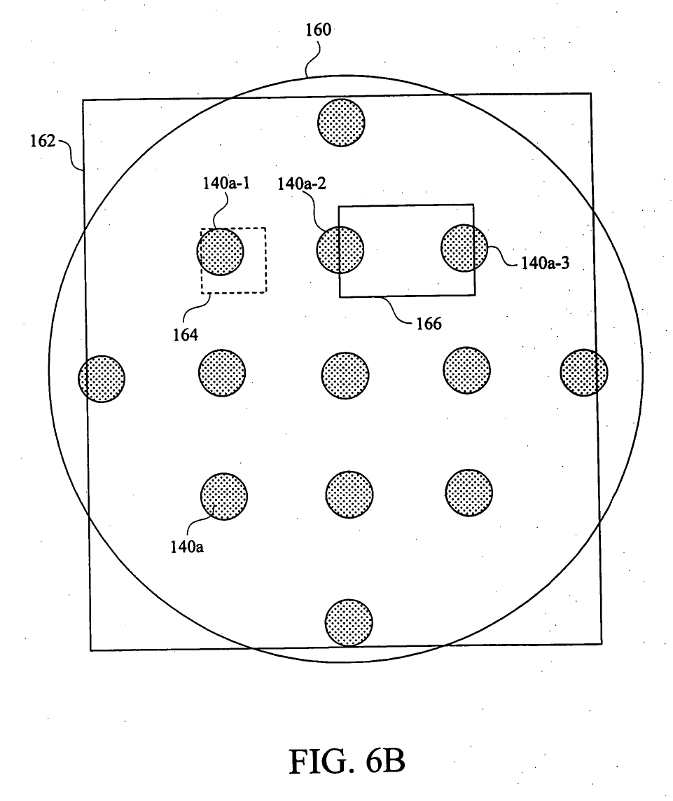

FIG. 6A shows an exemplary beam spot 160 as might be projected onto a semiconductor wafer, and representative locations of detector fibers 140a in the optical fiber aperture 135 (see FIG. 3), in accordance with one embodiment of the present invention. In one embodiment of the invention, as described above, the beam spot 160 is approximately 12.5 mm in diameter. As illustrated in FIG. 6A, representative locations of detector fibers 140a provide essentially complete coverage for reception of reflected light from beam spot 160. In one embodiment, such coverage accommodates light transmission realities such as scattering, attenuation, interference, and so forth.

FIG. 6B illustrates the projection of beam spot 160 of FIG. 6A onto an exemplary die 162, in accordance with an embodiment of the invention. Representative locations of detector fibers 140a in the optical fiber aperture 135 are again shown, and regions of interest 164, 166, are identified on the exemplary die 162. In accordance with an embodiment of the invention, the 13 detector fibers 140a provide optical signals from essentially the entire area or region of the exemplary die 162. As described above, the reflectance information from across essentially the entire exemplary die 162 can be monitored and analyzed. In one embodiment, the monitoring and analysis enables mathematical selection of the detector fiber 140a or combination of detector fibers 140a providing the best signal contrast, or the best content of information in the reflectant signature for a given process in real time. In FIG. 6B, region of interest 164 might return a signal through detector fiber 140a-1 matching a model for the particular feature, structure, cell, etc., for which a specific status or degree of processing (e.g., endpoint, etch-to-depth, etc.) is desired. Once a match is identified, detector fiber 140a-1 can be monitored real time until the desired status or degree of processing is achieved.

It should be appreciated that, in one embodiment, a match is identified between a received optic signal, processed through imaging spectrometer 138 (See FIG. 4) having a 2-D CCD detector array and a model processed signal for a specific parameter. In FIG. 6B, detector fiber 140a-1 may or may not be a specifically identifiable fiber or in a specifically identifiable location, but the signal returned is matched to specifically identify a desired parameter such as endpoint, etch-to-depth, etc.

Similarly, region of interest 166 might be identified by the signals from detector fibers 140a-2 and 140a-3, or by the combination of signals from fiber detectors 140a-2 and 140a-3. Once a match is identified, the detector fibers 140a-2, 140a-3, either independently or in combination, can be monitored and analyzed real time to identify the desired state or progress. As described above, one embodiment of the invention provides for identifying a match between a signal or combination of signals received from detector fibers 140a, or combination of detector fibers 140a, to any of a plurality of models appropriate for the type of process, stage of fabrication, structure(s) being fabricated, pattern density, and so forth, to evaluate process progress (i.e., endpoint), film depth (i.e., etch-to-depth), and any of a plurality of desired process parameters in real time enabling run-time precision. The detector fiber 140a selection is made in real time by a best match to an appropriate model, and then the detector fiber 140a, or combination of detector fibers 140a, is tracked through the fabrication process as appropriate or desired.

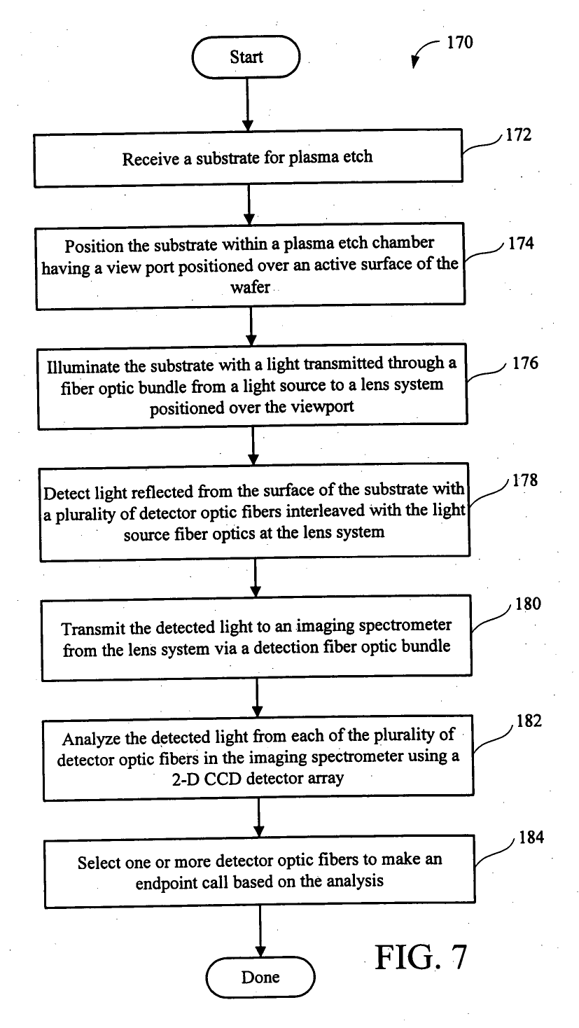

FIG. 7 is a flow chart diagram 170 illustrating the method operations for making an endpoint call in plasma etch operations, in accordance with one embodiment of the present invention. The method begins with operation 172 in which a substrate is received for plasma etch. In one example, the substrate is a semiconductor wafer having a plurality of structures defined and in the process of being fabricated therein. The structures can be of any type that is usually fabricated in and on semiconductor wafers such as integrated circuits, memory cells, and the like. In one embodiment, the structures are embedded dynamic random access memory structures having relatively large areas of generally open or featureless space with scattered regions of memory cell structures.

The method continues with operation 174 in which the substrate is positioned in a plasma etch chamber. An exemplary chamber is generally illustrated in FIG. 1. In one embodiment, the plasma etch chamber has a viewport in a top region of the chamber providing visual access to a top or active surface of the wafer to be processed in the plasma etch chamber.

In operation 176, the substrate is illuminated. A light source transmits light through a fiber optic bundle to a lens system that is positioned over the viewport. In one embodiment, the fiber optic bundle includes a plurality of optic fibers, which may range in number from approximately 60 to approximately 200. In another embodiment, the fiber optic bundle includes a plurality of optic fibers, which may range in number from approximately 20 to approximately 200. At the lens system, the light is collimated and aligned with the wafer surface, and transmitted in a beam having a spot of approximately 12.5 mm in diameter. In one embodiment, a 12.5 mm spot size is selected to correlate with an approximate 12.5 mm size of an exemplary die (the fundamental unit of the pattern repeated on the wafer), however the spot size can be larger or smaller in accordance with fabrication desires, pattern type, density, distribution, and any of a plurality of operating parameters based upon which spot size is modified accordingly.

The method continues with operation 178 in which light is reflected from the surface of the substrate and detected with a plurality of detector optic fibers. The detector optic fibers are interleaved with the light source optic fibers and a fiber optic aperture in the lens system. In one embodiment, 13 detector fibers are interleaved with the 60-200 light source fiber optics, dispersed across the fiber optic aperture to ensure complete reception coverage of the beam spot and light reflected therefrom.

Next, in operation 180, the detected light is transmitted to an imaging spectrometer from the lens system via a detection fiber optic bundle. Each of the detector fibers transmits detected light corresponding to a particular position or location from the surface of the substrate, as the detector fibers are interleaved with light source fibers and dispersed across the fiber optic aperture providing essentially complete reception coverage of the beam spot.

The method continues with operation 182 in which the detected light from each of the plurality of detector optic fibers is analyzed by the imaging spectrometer. The imaging spectrometer includes a 2-D CCD detector array for analyzing the detected light, and in one embodiment, provides a graphic display across light spectra for each detected reflectance signal.

The method concludes with operation 184 in which one or more detector optic fibers are selected to make an endpoint call based on the analysis. In one embodiment, the endpoint call is based on an analysis using an algorithm in which the signal from a particular detector optic fiber is selected to determine endpoint. By way of example, in a circumstance in which a known feature is in a known location on the substrate, and an known detector fiber is aligned with a known location corresponding to the feature, that known detector fiber is monitored and matched to a model for endpoint of that known feature.

In another embodiment, an endpoint call is based on an analysis in which an endpoint algorithm is run in parallel on the signals from all of the detector optic fibers. Each of the signals is examined to identify a greatest signal contrast of all of the signals. That particular signal is selected, and the optic fiber returning the selected signal is monitored for a match to endpoint signature.

In yet another embodiment, an endpoint call is based on an analysis in which an endpoint algorithm is run in parallel on the signals from all of the detector optic fibers, similar to the immediately preceding embodiment. In this embodiment, an endpoint algorithm would arbitrate among all of the signals using the error level from each signal. A signal is selected, and that signal is matched to an endpoint signal to make the endpoint call. In one embodiment, the arbitration may change the fiber of choice during the etching of the wafer if the relative error levels change. For example, a change in fiber of choice might occur if two fibers return errors that are very similar at the start of the wafer process but the errors evolve differently during the process. Once the endpoint call is made, the method is done.

With the above embodiments in mind, it should be understood that the invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Aspects of the invention can also be embodied as computer readable code on computer readable media. Computer readable media is any data storage device that can store data which can be thereafter read by a computer system. Computer readable media also includes an electromagnetic carrier wave in which the computer code is embodied. Examples of computer readable media include hard drives, network attached storage (NAS), read-only memory, random-access memory, CD-ROMs, CD-Rs, CD-RWs, magnetic tapes, and other optical and non-optical data storage devices. Computer readable media can also be distributed over a network coupled computer system so that the computer readable code is stored and executed in a distributed fashion.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A method for determining endpoint of a plasma etching operation of a surface on a wafer, the surface of the wafer having features being etched, comprising:
applying collimated light onto the surface of the wafer;
detecting reflected light from the surface of the wafer, the reflected light being detected by discrete detection regions, each detection region being configured to portray a unique signal across a frequency band;
identifying one of the detection regions to correlate with a model optical signal; and
executing endpoint of the plasma etching operation based on feedback from the identified one of the detected regions, the execution of endpoint being performed during the etching of the features on the surface.

2. The method of claim 1, wherein the collimated light is received from a source through a light source fiber optic bundle to a fiber optic aperture of a lens, the lens collimating and directing the collimated light to the surface of the wafer.

3. The method of claim 2, wherein the fiber optic aperture includes light detector fibers, the light detector fibers being interleaved with light source fibers from the light source fiber optic bundle at the fiber optic aperture.

4. The method of claim 3, wherein the discrete detection regions are defined by the light detector fibers, the discrete detection regions corresponding to an area on the surface of the wafer from which reflected light is detected by the light detector fibers.

5. The method of claim 1, further comprising:
transmitting the detected reflected light from the surface of the wafer to an imaging spectrometer;
analyzing the detected reflected light by the imaging spectrometer;
matching an optical signal from the analyzed detected reflected light to a model optical signal; and
selecting the matched optical signal to determine endpoint of the plasma etching operation.

6. The method of claim 5, wherein the imaging spectrometer includes a two dimensional charge coupled device (2D-CCD) array for analyzing the detected reflected light.

7. The method of claim 5, wherein the 2D-CCD array is configured to display the unique signal across a frequency band for each detection region.

8. A method for determining endpoint of plasma processing of a semiconductor wafer, comprising:
providing a light source;
providing a lens system to collimate and align light from the light source to an active surface of the semiconductor wafer;
interleaving a plurality of light detector fibers among light source fibers, the light source fibers transmitting light from the light source to the lens system and terminating in a fiber optic aperture at the lens system, the light detector fibers being interleaved among the light source fibers at the fiber optic aperture;
transmitting light through the lens system at the active surface of the semiconductor wafer;
receiving reflected light from the active surface of the semiconductor wafer at the plurality of light detector fibers;
providing an imaging spectrometer;
transmitting the received reflected light at the plurality of light detector fibers to the imaging spectrometer;
analyzing the received reflected light by the imaging spectrometer;
matching an optical signal from the analyzed received reflected light to a model optical signal; and
selecting the matched optical signal to determine endpoint of the plasma processing.

9. The method of claim 8, wherein the imaging spectrometer includes a 2-D CCD detector array.

10. The method of claim 9, wherein the 2-D CCD detector array provides a plot of at least one optical signal from the plurality of light detector fibers, the plot providing a visual representation of the at least one optical signal that can be matched to a model endpoint optical signal.

11. The method of claim 8, wherein the plasma processing of the semiconductor wafer is plasma etch processing.

12. The method of claim 8, wherein the plasma processing of the semiconductor wafer is plasma deposition processing.

13. The method of claim 8, wherein the matching of an optical signal from the analyzed received reflected light to a model optical signal is accomplished by matching an optical signal from each of the plurality of light detector fibers in parallel with the model analyzed signal and identifying a greatest signal contrast.

14. The method of claim 13, further comprising selecting the identified greatest signal contrast and monitoring the selected signal for a match to an endpoint signature.

15. The method of claim 8, wherein the matching of each of an optical signal from the analyzed received reflected light to a model optical signal is accomplished by matching an optical signal from each of the plurality of light detector fibers in parallel with the model analyzed signal and arbitrating the optical signal from each of the plurality of light detector fibers to identify a maximum acceptable error level.

16. The method of claim 15, further comprising selecting one of the optical signals from each of the plurality of light detector fibers to determine endpoint of a plasma process having a lowest error level below the maximum acceptable error level.
